(19) United States
(12) Patent Application Publication
(10) Pub. No.: US 2026/0246237 A1
(43) Pub. Date: Aug. 20, 2026

(54) Optical Device

(71) Applicant: NTT, Inc., Tokyo (JP)

(72) Inventors: Takuma Tsurugaya, Musashino-shi, Tokyo (JP); Koji Takeda, Musashino-shi, Tokyo (JP); Takuro Fujii, Musashino-shi, Tokyo (JP); Shinji Matsuo, Musashino-shi, Tokyo (JP)

(21) Appl. No.: 18/869,681

(22) PCT Filed: Jun. 1, 2022
(86) PCT No.: PCT/JP2022/022266

§ 371 Date: Nov. 26, 2024

(51) Int. Cl. H01S 5/20; H01S 5/10; H01S 5/11; H01S 5/12

(52) U.S. Cl. CPC H01S 5/2018; H01S 5/1014; H01S 5/11; H01S 5/12

(57) ABSTRACT

A first semiconductor layer and a second semiconductor layer that sandwich an active region and each being formed in contact with a side surface of a core are included. The first semiconductor layer and the second semiconductor layer are formed to be thinner than the core. The first semiconductor layer includes a first region and a first enlarged region, and the second semiconductor layer includes a second region and a second enlarged region. The first enlarged region has a trapezoidal shape in which a width increases from the first region side toward the third semiconductor layer side. The second enlarged region has a trapezoidal shape in which a width increases from the second region side toward the fourth semiconductor layer side.

### TECHNICAL FIELD

The present invention relates to an optical waveguide type optical device.

### BACKGROUND ART

A rib-type current injection structure has been proposed for a lateral current injection type membrane optical device that injects a current, into an active layer embedded in a core, in a lateral direction (Patent Literature 1). In this optical device, an optical waveguide structure of an active region in which the active layer is embedded employs a so-called rib-type. This structure enables the optical device to have advantages such as extremely strong confinement in the lateral direction, placement of electrode near the active layer, and highly efficient mode transformation between a channel-type passive waveguide. In particular, it is possible to constitute a laser having strong light confinement effect and low resistance by providing a reflecting unit constituted by a one-dimensional photonic crystal (hereinafter, referred to as a “nano-beam”) in passive optical waveguides sandwiching the active region in a waveguide direction.

A nano-beam mirror and the active region are connected by, in this laser, a tapered portion for changing core width of the channel-type passive optical waveguide and a mode-transform taper between the active region of a rib-type waveguide structure and the channel-type passive optical waveguide.

### CITATION LIST

### Patent Literature

Patent Literature 1: WO 2021/124440 A

### SUMMARY OF INVENTION

### Technical Problem

The technique described above, however, has the following problem. In a case where the laser having the conventional structure described above has an extremely short active layer length (for example, 2.5 μm or less), the mode transformation structure between the active region and the passive optical waveguide fails to achieve sufficient heat insulating property, so that a resonator Q-factor sufficiently high for achieving good laser characteristics (for example, sufficiently larger than 2,000) cannot be achieved.

If, in order to solve this problem, a slope of the taper of the mode transformation structure between the active region and the passive optical waveguide is further moderated from a typical value, a length of a portion connecting a thinned rib portion and an electrode-formed region becomes significantly short. The connection portion is a region serving as a current injection path, and shorter connection portion increases element resistance which deteriorates laser characteristics. As described above, there is a trade-off between a high resonator Q-factor and low resistance in the conventional structure.

The present invention has been made to solve the problem described above, and an object of the present invention is to reduce element resistance while achieving sufficient heat insulating property between an active region and a passive optical waveguide in a lateral current injection type membrane optical device.

### Solution to Problem

An optical device according to the present invention includes: a cladding layer; a core made of a compound semiconductor and formed on the cladding layer; an active layer embedded in an active region of the core; a first semiconductor layer made of an n-type compound semiconductor and a second semiconductor layer made of a p-type compound semiconductor, the first semiconductor layer and the second semiconductor layer being formed on the cladding layer, sandwiching the active region, and each being formed in contact with a side surface of the core; a third semiconductor layer made of an n-type compound semiconductor, formed on the cladding layer, being disposed so as to sandwich the first semiconductor layer with the active region, and connected to the first semiconductor layer; a fourth semiconductor layer made of a p-type compound semiconductor, formed on the cladding layer, being disposed so as to sandwich the second semiconductor layer with the active region, and connected to the second semiconductor layer; a first electrode connected to the third semiconductor layer; a second electrode connected to the fourth semiconductor layer; and a first passive optical waveguide and a second passive optical waveguide including the core in two regions sandwiching the active region and connected to the active region, wherein the first semiconductor layer and the second semiconductor layer are formed to be thinner than the core, the first semiconductor layer includes a first region having a trapezoidal shape in which a width decreases from the core side toward the third semiconductor layer side in plan view and a first enlarged region having a trapezoidal shape in which a width increases from the first region side toward the third semiconductor layer side, the second semiconductor layer includes a second region having a trapezoidal shape in which a width decreases from the core side toward the fourth semiconductor layer side in plan view and a second enlarged region having a trapezoidal shape in which a width increases from the second region side toward the fourth semiconductor layer side, and each of the first region and the second region has, at end portions in a waveguide direction, a tapered shape in which a width in plan view decreases as a distance from a central portion of the active region increases.

### Advantageous Effects of Invention

As described above, according to the present invention, the first enlarged region having the trapezoidal shape in which the width increases toward the third semiconductor layer is formed in the first semiconductor layer and the second enlarged region having the trapezoidal shape in which the width increases toward the fourth semiconductor layer is formed in the second semiconductor layer. The lateral current injection type membrane optical device is thus capable of reducing the element resistance while achieving sufficient heat insulating property between the active region and the passive optical waveguide.

### BRIEF DESCRIPTION OF DRAWINGS

FIG. 1A is a plan view illustrating a configuration of an optical device according to an embodiment of the present invention.

FIG. 1B is a sectional view of a part of the configuration of the optical device according to the embodiment of the present invention.

FIG. 2 is a plan view illustrating a comparative structure of the optical device.

FIG. 3A is a plan view illustrating a state of the optical device in an intermediate step to describe a method for manufacturing the optical device according to the embodiment of the present invention.

FIG. 3B is a sectional view illustrating a state of the optical device in an intermediate step to describe the method for manufacturing the optical device according to the embodiment of the present invention.

FIG. 3C is a plan view illustrating a state of the optical device in an intermediate step to describe a method for manufacturing the optical device according to the embodiment of the present invention.

FIG. 3D is a sectional view illustrating a state of the optical device in an intermediate step to describe the method for manufacturing the optical device according to the embodiment of the present invention.

FIG. 3E is a sectional view illustrating a state of the optical device in an intermediate step to describe the method for manufacturing the optical device according to the embodiment of the present invention.

FIG. 3F is a sectional view illustrating a state of the optical device in an intermediate step to describe the method for manufacturing the optical device according to the embodiment of the present invention.

FIG. 4 is a plan view illustrating another comparative structure of the optical device.

FIG. 5 is a characteristic diagram illustrating a result of calculating a resonator Q-factor by sweeping Wₜₚ₂ in an old structure B, where an active layer length L_{BH} is 2.5 μm, a thickness t_{side} of each of a first semiconductor layer 104″ and a second semiconductor layer 105″ is 100 nm, and Lₜₚ₂ is 0.4 μm.

FIG. 6 is a plan view illustrating another comparative structure of the optical device.

FIG. 7 is a characteristic diagram (a) plotting a function of the active layer length L_{BH} obtained by calculating a normalized resistance value R′ based on Formula (1), and a characteristic diagram (b) plotting a normalized resistance value R′L_{BH} per unit active layer length obtained by multiplying R′ by L_{BH}.

### DESCRIPTION OF EMBODIMENTS

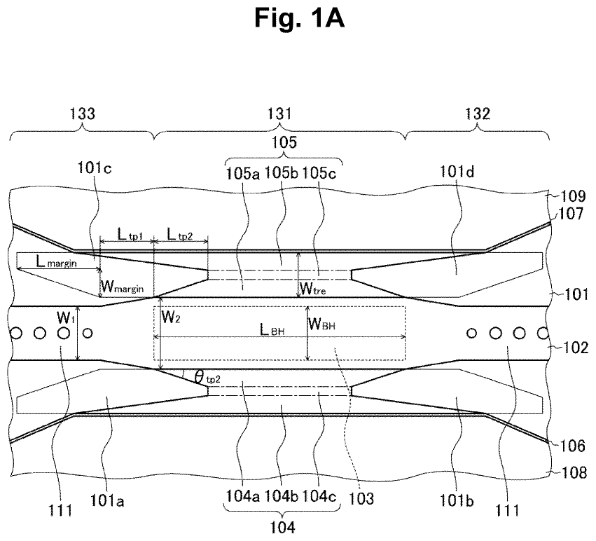

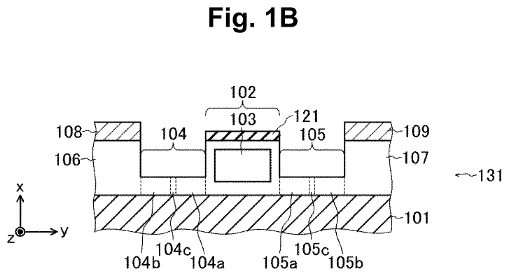

Hereinafter, an optical device according to an embodiment of the present invention is described with reference to FIGS. 1A and 1B. FIG. 1B illustrates a cross-section along a plane perpendicular to a waveguide direction. In FIG. 1B, an x-axis direction (an x direction) is a thickness direction, a y-axis direction (a y direction) is a current injection direction, and a z-axis direction (a z direction) is the waveguide direction.

This optical device includes a cladding layer 101, a core 102 formed on the cladding layer 101, an active layer 103 embedded in the core 102, and a first semiconductor layer 104 and a second semiconductor layer 105 that are formed on the cladding layer 101 to be parallel to a face of the cladding layer 101, sandwiches an active region 131 in a direction perpendicular to the waveguide direction (the z direction), that is the y direction, and are each formed in contact with a side surface of the core 102.

The cladding layer 101 is made of, for example, silicon oxide. For example, a silicon oxide layer formed on a substrate made of Si or the like can be used as the cladding layer 101. The core 102 is made of, for example, a group III-V compound semiconductor such as InP. The core 102 can be formed by, for example, depositing InP on the cladding layer 101 by a well-known metal organic chemical vapor deposition method or the like.

The active layer 103 is embedded in the active region 131 of the core 102. The active layer 103 has an outer shape of, for example, a rectangular parallelepiped shape. In addition, the first semiconductor layer 104 and the second semiconductor layer 105 are disposed so as to sandwich the active region 131. The first semiconductor layer 104 is made of, for example, an n-type group III-V compound semiconductor such as n-type InP. In addition, the second semiconductor layer 105 is made of, for example, a p-type group III-V compound semiconductor such as p-type InP.

This optical device also includes a third semiconductor layer 106 which is formed on the cladding layer 101, is disposed so as to sandwich the first semiconductor layer 104 with the active region 131, and is connected to the first semiconductor layer 104. This optical device also includes a fourth semiconductor layer 107 which is formed on the cladding layer 101, is disposed so as to sandwich the second semiconductor layer 105 with the active region 131, and is connected to the second semiconductor layer 105. The third semiconductor layer 106 is made of an n-type group III-V compound semiconductor such as n-type InP. In addition, the fourth semiconductor layer 107 is made of a p-type group III-V compound semiconductor such as p-type InP.

This optical device also includes a first electrode 108 electrically connected to the third semiconductor layer 106 and a second electrode 109 electrically connected to the fourth semiconductor layer 107. In this example, the cladding layer 101 side is defined as the lower side, and air is defined as a cladding on an upper side of the core 102.

First, this optical device has the first semiconductor layer 104 and the second semiconductor layer 105 formed to be thinner than the core 102. The thin region can be referred to as a “trench region”. In this example, the core 102, the first semiconductor layer 104, the second semiconductor layer 105, the third semiconductor layer 106, and the fourth semiconductor layer 107 are integrally formed. In addition, a first passive optical waveguide 132 and a second passive optical waveguide 133 disposed so as to sandwich the active region 131 in the waveguide direction are optically connected to the active layer 103 (the active region 131).

The active region 131, in which the first semiconductor layer 104 and the second semiconductor layer 105 are formed to be thinner than the core 102, has a so-called rib-type optical waveguide structure in which the first semiconductor layer 104 and the second semiconductor layer 105 are slabs. The first passive optical waveguide 132 and the second passive optical waveguide 133, on the other hand, have a so-called optical channel-type waveguide structure.

The optical device according to the embodiment includes, in addition to the configurations described above, a first region 104a and a first enlarged region 104b in the first semiconductor layer 104 and a second region 105a and a second enlarged region 105b in the second semiconductor layer 105.

The first region 104a has a trapezoidal shape in which the width decreases from the core 102 side toward the third semiconductor layer 106 side in plan view. The first enlarged region 104b has a trapezoidal shape in which a width increases from the first region 104a side toward the third semiconductor layer 106 side. The second region 105a has a trapezoidal shape in which a width decreases from the core 102 side toward the fourth semiconductor layer 107 side in plan view. The second enlarged region 105b has a trapezoidal shape in which a width increases from the second region 105a side toward the fourth semiconductor layer 107 side.

In this example, the first region 104a and the second region 105a each has an isosceles trapezoidal shape with the active layer 103 side serving as a base in plan view. In addition, in this example, the first enlarged region 104b has an isosceles trapezoidal shape whose base is on the third semiconductor layer 106 side in plan view, and the second enlarged region 105b has an isosceles trapezoidal shape whose base is on the fourth semiconductor layer 107 side in plan view. In addition, each of the first region 104a and the second region 105a has, at end portions in the waveguide direction, a tapered shape in which a width in plan view decreases as a distance from a central portion of the active region 131 (the active layer 103) increases.

In addition, in this example, the first semiconductor layer 104 includes a first neck region 104c that connects the first region 104a and the first enlarged region 104b to each other, and the second semiconductor layer 105 includes a second neck region 105c that connects the second region 105a and the second enlarged region 105b to each other. The first neck region 104c is formed to have a uniform width from the core 102 side to the third semiconductor layer 106 side in plan view. The second neck region 105c is formed to have a uniform width from the core 102 side to the fourth semiconductor layer 107 side in plan view.

Furthermore, this example includes a first recess 101a and a second recess 101b formed in regions of the cladding layer 101 sandwiching the first semiconductor layer 104 in the waveguide direction, and a third recess 101c and a fourth recess 101d formed in regions of the cladding layer 101 sandwiching the second semiconductor layer 105 in the waveguide direction. Each of the first recess 101a, the second recess 101b, the third recess 101c, and the fourth recess 101d is formed such that a corresponding distance between a straight portion of the core 102 (a corresponding distance in the y direction) of the first passive optical waveguide 132 and the second passive optical waveguide 133 increases as the distance from the active region 131 increases.

In this case, the first passive optical waveguide 132 and the second passive optical waveguide 133, disposed so as to sandwich the active region 131 in the waveguide direction, are each optically connected to the active layer 103 (the active region 131) via a tapered region whose core width decreases as the distance from the active region 131 increases. Core widths of the first passive optical waveguide 132 and the second passive optical waveguide 133 may be the same as a core width of the active region 131.

The optical device according to the embodiment may also include a resonator 111 formed across the active region 131 in the waveguide direction. The resonator 111 may be omitted. In this example, the resonator 111 is constituted by a photonic crystal structure formed in the core 102. In the photonic crystal structure, a plurality of through-holes penetrating the core 102 in the thickness direction are arranged, in the waveguide direction, in the core 102 of the first passive optical waveguide 132 and the second passive optical waveguide 133 (a nano-beam). Instead of the photonic crystal structure, a diffraction grating may be formed on the core 102 of each of the first passive optical waveguide 132 and the second passive optical waveguide 133 and the resonator may be configured using the diffraction grating as a reflection unit.

By forming the resonator (the reflection unit) 111 as described above and sandwiching the active region 131 with the resonator 111 to obtain a structure in which light is confined in the active region 131, the optical device can operate as a current injection laser. As to a mechanism of light extraction, for example, number of periods of the photonic crystal structure constituting the resonator 111 of the first passive optical waveguide 132 can be reduced, and a transmission component resulting therefrom can be used as an output. Alternatively, for example, a Si core may be formed in the core 102 of the first passive optical waveguide 132 at the closest possible place that allows optical coupling, and oscillating light can then be extracted from this passive optical waveguide having the Si core.

The optical device according to the embodiment described above includes the first region 104a and the first enlarged region 104b and the second semiconductor layer 105 includes the second region 105a and the second enlarged region 105b, so that a heat insulating property of the tapered structure between the active region 131 serving as the rib-type optical waveguide and the first passive optical waveguide 132 and the second passive optical waveguide 133 serving as the channel-type optical waveguide can be significantly improved as compared to conventional structures. As a result, for example, in a case where the optical device is a laser, a resonator Q-factor can be improved as compared to the conventional structures. Further, the optical device according to the embodiment is capable of reducing element resistance as compared to the conventional structures.

In addition, the optical device according to the embodiment includes the first recess 101a, the second recess 101b, the third recess 101c, and the fourth recess 101d, and it is thus possible to manufacture the optical device by a practical and easily implementable method, which eliminates the inconvenience on device structures generated when employing this manufacturing method and enables achievement of good device characteristics.

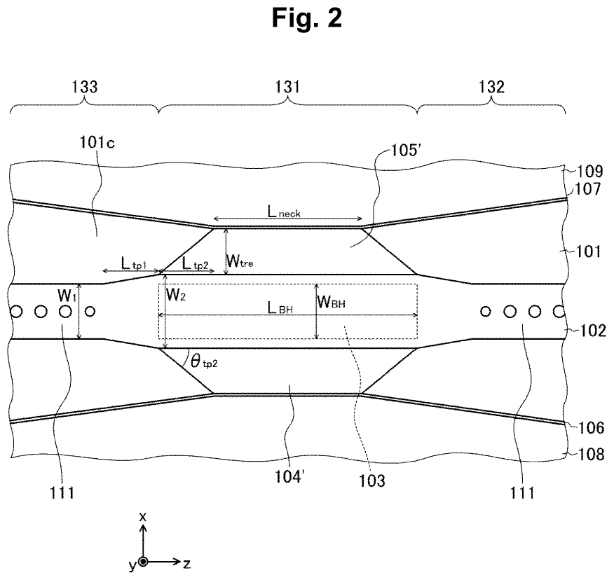

Here, the optical device according to the embodiment will be described in detail by comparison with a conventional structure illustrated in FIG. 2. In the conventional structure (hereinafter, referred to as an “old structure A”), a first semiconductor layer 104′ and a second semiconductor layer 105′, sandwiching an active region 131 and formed in contact with the corresponding side surface of a core 102, has a trapezoidal shape whose width decreases as the distance from the core 102 side increases in plan view. In this structure, the active region 131 and each of a first passive optical waveguide 132 and a second passive optical waveguide 133 are tapered with a steep structure given by a tangent Wₜᵣₑ/Lₜₚ₂, where a length in the z direction is denoted by Lₜₚ₂, a length in the x direction is denoted by Wₜᵣₑ. Hereinafter, the connection between the active region 131 which is the rib-type optical waveguide and each of the first passive optical waveguide 132 and the second passive optical waveguide 133 which is the channel-type optical waveguide is referred to as a “rib-channel”.

The optical device according to the embodiment employs, on the other hand, a taper with a sufficiently gentle slope given by a tangent Wₜₚ₂/Lₜₚ₂ (Wₜₚ₂<Wₜᵣₑ), which is obtained by providing the first region 104a and the second region 105a as illustrated in FIG. 1A. Here, a length in the z direction is denoted by Lₜₚ₂. Furthermore, according to the embodiment, the trench region to be the current injection path, in which the mode of each of the first passive optical waveguide 132 and the second passive optical waveguide 133 is transformed to that of the rib-type by the corresponding taper of the first region 104a and the second region 105a and passes through the neck portion having a width W_{neck}, is enlarged, in the z direction, by a shape given by a tangent Wₑₓₜ/Lₑₓₜ. These enlarged portions become the first enlarged region 104b and the second enlarged region 105b. Each of the neck portion is a portion defined by a region where the first neck region 104c and the second neck region 105c are formed in the z direction.

In addition, each of the first recess 101a, the second recess 101b, the third recess 101c, and the fourth recess 101d formed in the cladding layer 101 is tapered so as to separate outward from the resonator 111 (a nano-beam mirror) by a tapered shape given by a tangent W_{margin}/L_{margin}. The old structure A illustrated in FIG. 2 gives no consideration in a practical manufacturing process; therefore, the old structure A does not include the first recess 101a, the second recess 101b, the third recess 101c, and the fourth recess 101d, that is, etching regions of the cladding layer 101.

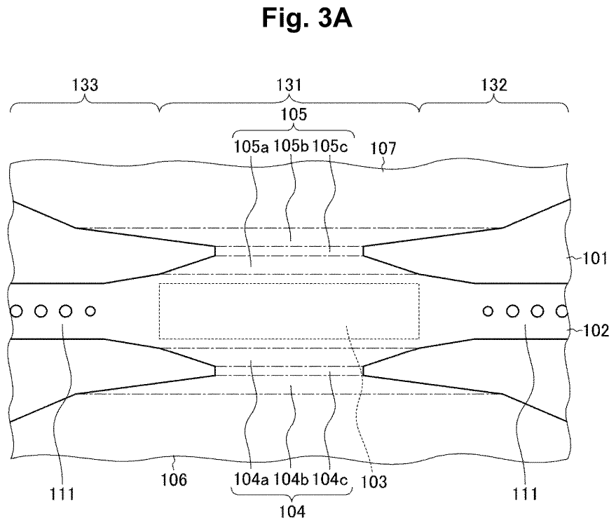

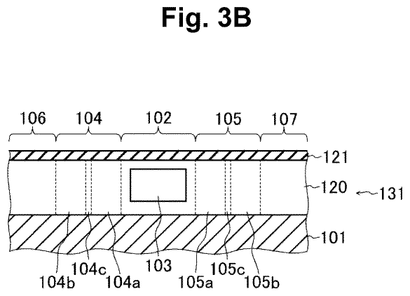

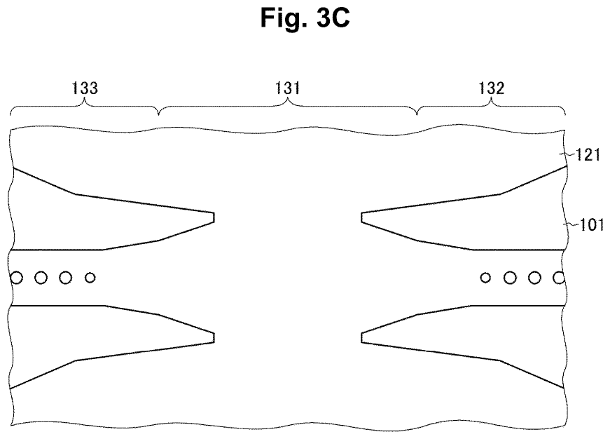

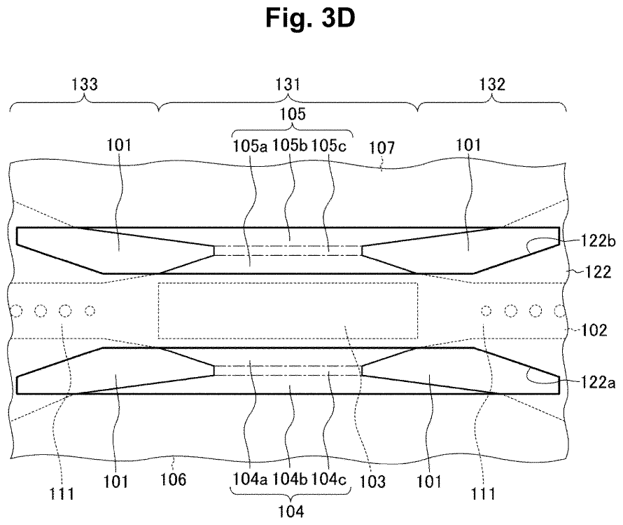

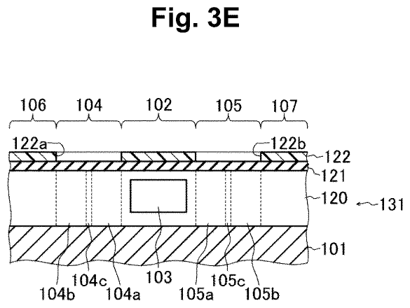

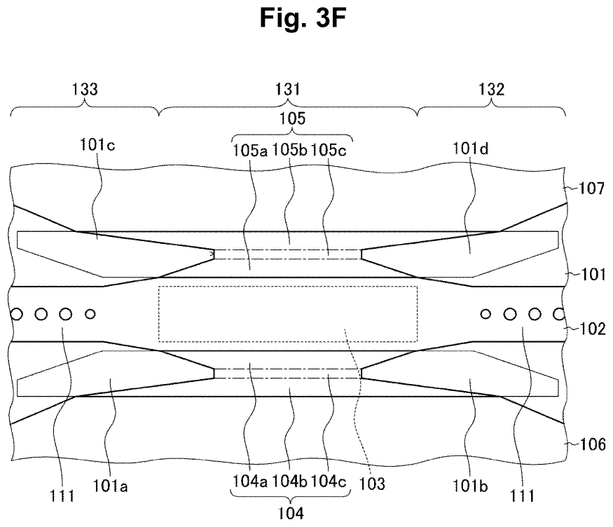

Next, a method for manufacturing the optical device according to the embodiment will be described with reference to FIGS. 3A to 3F. First, for example, a thin semiconductor layer made of InP is formed on the cladding layer 101, and then an InP-based semiconductor layer or a semiconductor stacked structure to be the active layer 103 is formed thereon. The semiconductor stacked structure is, for example, a multiple quantum well structure. This may be prepared by, for example, bonding a wafer made of a group III-V compound semiconductor, in which the semiconductor stacked structure described above is crystal-grown, and a Si wafer having an oxide film to be the cladding layer 101 together. Thereafter, the InP-based semiconductor layer or the semiconductor stacked structure to be the active layer 103 is patterned by known lithography and etching techniques to form the active layer 103.

Next, InP is regrown from the thin semiconductor layer made of InP, which is exposed around the active layer 103 due to forming of the active layer 103, to form a thick semiconductor layer 120 in which the active layer 103 is embedded (with a thickness of t_{membrane}), and impurities are introduced to form regions of each conductivity type (Reference Document 1).

Next, regions to be the first semiconductor layer 104 and the second semiconductor layer 105 and regions to be the third semiconductor layer 106 and the fourth semiconductor layer 107 are formed by known lithography and etching techniques. First, for example, a silicon oxide film is formed on the semiconductor layer 120 and patterned by known lithography and etching techniques to form a mask pattern 121.

Next, the regions to be the first semiconductor layer 104 and the second semiconductor layer 105 and the regions to be the third semiconductor layer 106 and the fourth semiconductor layer 107 can be formed by etching processing the semiconductor layer 120 using the mask pattern 121 as a mask. The shapes of the core 102 of the first passive optical waveguide 132 and the second passive optical waveguide 133 and the photonic crystal structure constituting the resonator 111 are also formed in this process. All the InP (the semiconductors) in the regions other than the first passive optical waveguide 132, the second passive optical waveguide 133, and the core 102 are removed to expose the upper surface of the cladding layer 101 (FIGS. 3A and 3B).

At this stage, as illustrated in FIG. 3B, the mask pattern 121 having the planar shape illustrated in the plan view of FIG. 3C remains on the semiconductor layer 120 in which the regions to be the first semiconductor layer 104 and the second semiconductor layer 105 and regions to be the third semiconductor layer 106 and the fourth semiconductor layer 107 are formed.

Next, as illustrated in FIGS. 3D and 3E, a resist pattern 122 including an opening 122a and an opening 122b is formed on the mask pattern 121. The resist pattern 122 may be formed by, for example, applying a positive resist to form a resist film and performing exposure and development by a known photolithography technique. The semiconductor layer 120 is patterned with the mask pattern 121, so that a part of the upper surface of the cladding layer 101 which is exposed can be seen from the opening 122a and the opening 122b. This portion becomes the first recess 101a, the second recess 101b, the third recess 101c, and the fourth recess 101d.

Next, the portion of the mask pattern 121 exposed from the opening 122a and the opening 122b is etched and removed using the manufactured resist pattern 122. The part of the upper surface of the cladding layer 101 which is exposed as described above is also etched at this time, so that the first recess 101a, the second recess 101b, the third recess 101c, and the fourth recess 101d are formed.

In this way, the mask pattern 121 in the regions to be the first semiconductor layer 104 and the second semiconductor layer 105 is removed to form the first recess 101a, the second recess 101b, the third recess 101c, and the fourth recess 101d, and the resist pattern 122 is removed to expose the region to be the first semiconductor layer 104, and the second semiconductor layer 105. At this time point, the thicknesses of the regions to be the first semiconductor layer 104 and the second semiconductor layer 105 and the regions to be the third semiconductor layer 106 and the fourth semiconductor layer 107 remain t_{membrane}.

Next, by etching processing using the mask pattern 121 which is removed of the regions to be the first semiconductor layer 104 and the second semiconductor layer 105, the regions to be the first semiconductor layer 104 and the second semiconductor layer 105 of the semiconductor layer 120 are etched by an appropriate thickness (t_{membrane}−t_{side}) and thinned to a thickness t_{side}. As a result, the first semiconductor layer 104 (the first region 104a, the first enlarged region 104b, and the first neck region 104c) and the second semiconductor layer 105 (the second region 105a, the second enlarged region 105b, and the second neck region 105c) that are thinner than the other portions are formed as illustrated in FIG. 3F.

Thereafter, the optical device (a photonic crystal laser diode) illustrated in FIGS. 1A and 1B can be obtained by forming electrodes as described in Reference Document 1. Although not illustrated in FIG. 1B, (a part of) the mask pattern 121 used to form the first semiconductor layer 104 and the second semiconductor layer 105, which are thinner than the other portions, may remain on the area of the core 102 on which no electrode is formed. Even if a part of the mask pattern 121 remains on the core 102 as described above, this has no affect on characteristics of the optical device.

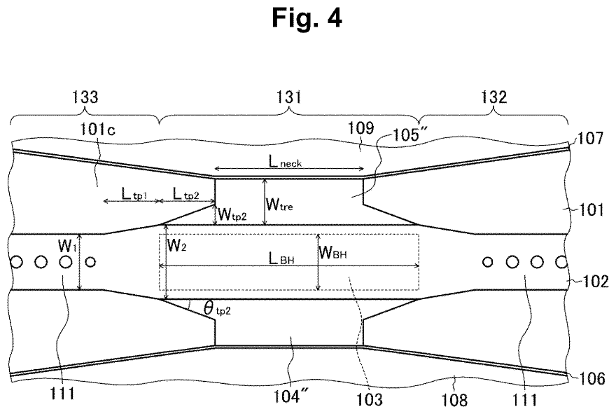

Next, effects on the device characteristics and advantages in the device manufacturing process brought by the present invention will be described. Hereinafter, in order to separately discuss the effects of the present invention, consideration is given to a structure illustrated in FIG. 4 (hereinafter, referred to as an “old structure B”) as an intermediate structure between the optical device according to the embodiment described with reference to FIGS. 1A and 1B and the old structure A described with reference to FIG. 2. A taper structure for mode transformation in a rib-channel (a rib-channel transformation taper) of a first semiconductor layer 104″ and a second semiconductor layer 105″ of the old structure B is same as that of the embodiment, while the other structures of the old structure B are same as those of the old structure A.

In the following calculation, values shown in Table 1 are commonly used as typical parameters of the device structures.

TABLE 1

| Common parameter | Value |
|---|---|
| T_{membrane} (nm) | 250 |
| W_{BH} (μm) | 0.35 |
| W₁ (μm) | 0.5 |
| W₂ (μm) | 0.6 |
| Lₜₚ₁ (μm) | 0.4 |
| Wₜᵣₑ (μm) | 0.7 |

In addition, the optical device, which has obtained a laser structure by including the resonator 111, employs a three-dimensional finite difference time domain for calculating the resonator Q-factor, and the resonator 111 made of the nano-beam having sufficiently low transmittance is provided in both the +z direction and the −z direction, so that an intrinsic Q-factor without a decrease caused by light extraction can be obtained.

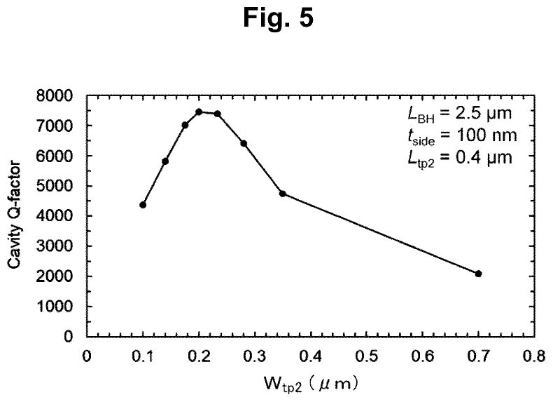

FIG. 5 illustrates a result of calculating a resonator Q-factor of an old structure B by sweeping Wₜₚ₂, where an active layer length L_{BH} is 2.5 μm, a thickness t_{side} of each of the first semiconductor layer 104″ and the second semiconductor layer 105″ is 100 nm, and Lₜₚ₂ is 0.4 μm. The resonator Q-factor reaches a maximum value at approximately Wₜₚ₂=0.2 μm, and it can be seen that there is an optimal Wₜₚ₂ at a predetermined Lₜₚ₂. FIG. 5 is same to the old structure A in taking Wₜₚ₂=Wₜᵣₑ=0.7 μm, and it can be seen that a Q-factor significantly higher than that of the old structure A can be obtained by optimizing Wₜₚ₂ in the old structure B.

Dependency of the resonator Q-factor on Wₜₚ₂ as described above can be understood by the following mechanism. First, in a case where Wₜₚ₂ is too wide, the slope of the rib-channel transformation taper becomes too steep as in the old structure A and mode transformation between the both cannot be performed with good heat insulating property. As a result, the Q-factor deteriorates. In a case where Wₜₚ₂ is too narrow, on the other hand, the heat insulating property in the rib-channel transformation taper portion is favorable; however, the taper ends before the mode on the active region 131 side is sufficiently widened, which causes a portion parallel (that is, an angle of 90 degrees) to the x-axis (a portion having a length L_{neck}) to suddenly appear. This also deteriorates the heat insulating property.

An optimal Wₜₚ₂ that gives a maximal and maximum Q-factor can thus be obtained by balancing the both. The present invention provides a solution to this non-trivial extreme problem and provides an optimal Wₜₚ₂ from which the highest Q-factor is achieved at a given Lₜₚ₂. This example assumes a very short value of L_{BH}=2.5 μm as the active layer length and a thickness value of t_{side}=100 nm as the thicknesses of each of the first semiconductor layer and the second semiconductor layer which are severe conditions for obtaining a high Q-factor. Therefore, the Q-factor in the old structure A is about 2,000 which is insufficient for obtaining good laser characteristics; however, the Q-factor is increased to about 7, 500 while commonly using Lₜₚ₂, by employing the rib-channel transformation taper optimized by the present invention. This is a significant and important improvement in obtaining good laser characteristics.

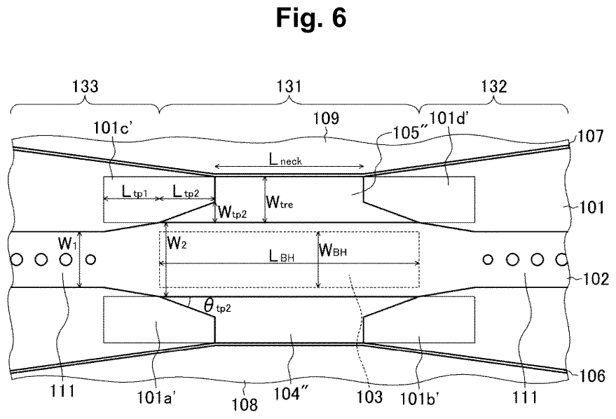

Next, consideration is given to a structure illustrated in FIG. 6 (hereinafter, referred to “an old structure B′”) as a structure closer to that of the optical device according to the embodiment. As is clear from the figure, the old structure B′ has a structure in which a first recess 101a′, a second recess 101b′, a third recess 101c′, and a fourth recess 101d′ are added to the old structure B, thereby causing gouging to a lower portion of the cladding layer 101. No portion of the first recess 101a′, the second recess 101b′, the third recess 101c′, and the fourth recess 101d′ extends in the region of the straight portion of a core 102 of a second passive optical waveguide 133.

In a case where the manufacturing processes described with reference to FIGS. 3A to 3F are employed, the regions to be formed with the recesses described above are indispensable in consideration of the alignment accuracy in practical manufacturing processes. Ideally, only the region to be thinned, which is to become the fourth semiconductor layer and fifth semiconductor layer, are patterned with this mask pattern used for thinning layers. For this purpose, the opening of the resist pattern 122 described with reference to FIG. 3D is formed only in a target region.

Practically, however, the patterning as described above is very difficult due to the limitation in writing resolution and alignment accuracy of lithography processes. An attempt of only exposing the region to be thinned, which is to become the fourth semiconductor layer and the fifth semiconductor layer, may lead to problems such as blunting of a tip shape of the rib-channel transformation taper and generation of residues of the semiconductor layer resulting from misalignment. In order to avoid these problems, as described with reference to FIG. 3D, the resist pattern 122 including the opening 122a and the opening 122b wider than the regions to be the fourth semiconductor layer and the fifth semiconductor layer are used.

As illustrated in FIG. 6, however, when the first recess 101a′, the second recess 101b′, the third recess 101c′, and the fourth recess 101d′ are formed, the gouging of the cladding layer 101 suddenly appears when viewed along the z-axis direction. This sudden appearance is sensed by the mode of the laser resonator, which significantly decreases the Q-factor.

The first recess 101a, the second recess 101b, the third recess 101c, and the fourth recess 101d of the embodiment solve the problem described above. Table 3 shows the results of calculating the Q-factors of the old structure B, the old structure B′, and the optical device according to the embodiment, that is, a proposed structure, using the values shown in Table 2 as common parameters. Here, Lₜₚ₂ and Wₜₚ₂ are optimum values calculated from FIG. 5. Table 3 also shows the parameters of the proposed structure which are assumed for calculation. The parameter values are typical values for obtaining good device characteristics in the proposed structure.

TABLE 2

| Common parameter | Value |
|---|---|
| L_{BH} (μm) | 2.5 |
| T_{side} (nm) | 75 |
| Lₜₚ₂ (μm) | 0.4 |
| Wₜₚ₂ (μm) | 0.2 |

TABLE 3

| | Old structure | Old structure | Proposed |
|---|---|---|---|
| Parameter | B | B′ | structure |
| Under cladding of | Etched | Not etched | Not etched |
| marginal region | | | |
| etched or not | | | |
| W_{neck} (μm) | — | — | 0.1 |
| Lₑₓₜ (μm) | 0 | 0 | 3.4 |
| Wₑₓₜ (μm) | — | — | 0.4 |
| L_{marqin} (μm) | — | 0 | 3 |
| W_{marquin} (μm) | — | — | 0.3 |
| Resonator Q-factor | 8.49 × 10³ | 4.89 × 10³ | 7.78 × 10³ |

First, the old structure B, in which no consideration is given to the gouging of the cladding layer 101 in the region to be the recess, reaches a good Q-factor of 8.49×10³. This is an advantage brought by using the optimized Lₜₚ₂ and Wₜₚ₂. In the old structure B′ obtained by adding the first recess 101a′, the second recess 101b′, the third recess 101c′, and the fourth recess 101d′, on the other hand, the Q-factor decreases to 4.89×10³, that is, decreases by 42%.

On the other hand, the Q-factor of the proposed structure is 7.78×10³, which decreases from the Q-factor of the old structure B only by 8.4%. That is, the proposed structure is capable of, while favorably reducing a decrease in the Q-factor caused by the formation of the recess in the cladding layer 101, achieving low resistance by increasing the lengths of the first semiconductor layer and the second semiconductor layer, in the z direction, used for current injection without significantly decreasing the Q-factor.

Although the first enlarged region 104b of the first semiconductor layer 104 and the second enlarged region 105b of the second semiconductor layer 105, whose length is increased in the z direction, are placed near the first passive optical waveguide 132 and the second passive optical waveguide 133 forming the nano-beam, there is no significant decrease in the Q-factor because of the following reason. In a case where other optical waveguides or slabs having modes with close effective refractive index is placed near an optical waveguide or a nano-beam, directional coupling typically occurs between the two. In a case where the optical waveguide or the nano-beam forms a resonator, the resulting directional coupling effectively functions as light extraction which reduces the Q-factor.

In the proposed structure, on the other hand, while various lateral modes are formed in the third semiconductor layer 106 on which the first electrode 108 is formed and the fourth semiconductor layer 107 on which the second electrode 109 is formed, since the first semiconductor layer 104 and the second semiconductor layer 105 are thinned, the mode distribution is defined by the strong refractive index contrast between the first semiconductor layer 104 and the second semiconductor layer 105 and the thicker third semiconductor layer 106 and fourth semiconductor layer 107. As a result, very little mode oozes into the first semiconductor layer 104 and the second semiconductor layer 105. Therefore, even if there are regions that the first enlarged region 104b and the second enlarged region 105b proximate the first passive optical waveguide 132 and the second passive optical waveguide 133, no significant optical coupling occurs against the third semiconductor layer 106 and the fourth semiconductor layer 107, so that it is possible to maintain a high Q-factor.

Next, in order to discuss the reduction effect of resistance according to the present invention, the element resistance of each structure will be compared. Series resistance components of the thinned portions of the first semiconductor layer and the second semiconductor layer are dominant in the rib-type current injection structure; their resistance component will be considered below. A resistivity p and a thickness t_{side} of the first semiconductor layer and the second semiconductor layer are common in each structure, and a dimensionless resistance value R′ normalized by these common factors is calculated by the following equation.

$$[ Math . 1 ]$$

$${R}^{′} ≡ \frac{{Rt}_{side}}{ρ} = {\int }_{0}^{{W}_{tre}} \frac{dx}{{L}_{tre} ( x )} \qquad ( 1 )$$

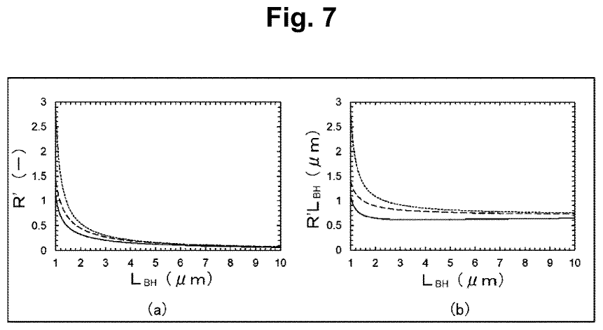

In the above formula, R represents a series resistance value of the first semiconductor layer and the second semiconductor layer and Lₜᵣₑ (x) represents a length of the first semiconductor layer and the second semiconductor layer, in an optical axis direction (the waveguide direction), at the coordinate x. FIG. 7(a) is obtained by calculating the normalized resistance value R′ based on the formula (1) and plotting the calculated value as a function of the active layer length L_{BH} for each of the three structures, that is, the proposed structure, the old structure A, and the old structure B. In addition, FIG. 7(b) is obtained by plotting their normalized resistance value per unit active layer length R′ L_{BH}, Which is obtained by multiplying R′ by L_{BH}. Typical values shown in Table 1, Table 2, and Table 3 are used as values of the parameters required for calculating the normalized resistance value (Wₜᵣₑ, Lₜₚ₂, Wₜₚ₂, W_{neck}, Lₑₓₜ, and Wₑₓₜ). In addition, solid lines indicate the proposed structure, broken lines indicate the old structure A, and dotted lines indicate the old structure B in FIG. 7.

As illustrated in FIG. 7, it can be seen that the proposed structure has achieved a significantly lower resistance value than either of the old structure A or the old structure B. This reduction effect of resistance is remarkable in a case of an extremely short active layer which is relatively largely affected by an increase in conductance derived from the first enlarged region and the second enlarged region. For example, the resistance is reduced by 28.6% from the old structure A at L_{BH}=2.5 μm and reduced by 25.9% from the old structure A at L_{BH}=1.3 μm.

As described above, according to the present invention, the first enlarged region having the trapezoidal shape in which the width increases toward the third semiconductor layer is formed in the first semiconductor layer and the second enlarged region having the trapezoidal shape in which the width increases toward the fourth semiconductor layer is formed in the second semiconductor layer. The lateral current injection type membrane optical device is thus capable of reducing the element resistance while achieving sufficient heat insulating property between the active region and the passive optical waveguide. In addition, according to the present invention, the structure described above can be achieved by practical and easy manufacturing processes.

One feature of the present invention is that the structure design of the rib-channel transformation taper is put into a form of optimization of the parameter Wₜₚ₂, thereby optimally designing a taper structure capable of obtaining the highest resonator Q-factor at a predetermined Lₜₚ₂. If Lₜₚ₂ is too long, the length L_{neck} of the neck portion becomes too short which increases the resistance value, so that Lₜₚ₂ cannot be unnecessarily long. This optimization is made based on a non-obvious extreme value problem, that is, the heat insulating property deteriorates if Wₜₚ₂ is too wide or too narrow.

After ensuring sufficient heat insulating property by the characteristic structure described above, the first semiconductor layer and the second semiconductor layer which are thinned are expanded in the waveguide direction by the enlarged region, and thereby low resistance is achieved without impairing the high resonator Q-factor. This achievement utilizes a unique property of the rib-type current injection structure, that is, the mode of the fourth semiconductor layer and the fifth semiconductor layer, in each of which the electrode is formed, is strongly localized in this region and hardly oozes into the first semiconductor layer and the second semiconductor layer which are thinned; therefore, even if each of the first semiconductor layer and the second semiconductor layer includes a region close to the first passive optical waveguide and the second passive optical waveguide, no significant optical coupling occurs.

In addition, the high Q-factor and the low resistance described above can be achieved at the same time by uniquely devising the writing pattern used in the lithography process, which is newly proposed as the practical and easily implementable manufacturing processes in the embodiment. The main object of providing the structure having the taper length of about several μm in the recess formed in the cladding layer to dissipate heat to the outside is to reduce a decrease in the Q-factor derived from the recess formed in the cladding layer. The first semiconductor layer and the second semiconductor layer to be thinned can be enlarged only after, in addition n to the arrangement described above, securing a wide manufacturing margin region for forming the region to be thinned and forming holes of a mask pattern over a wide range.

A part or entire embodiment described above is also described as the following supplementary notes, but are not limited thereto.

### [Supplementary Note 1]

An optical device including:
a cladding layer;
a core made of a compound semiconductor and formed on the cladding layer;
an active layer embedded in an active region of the core;
a first semiconductor layer made of an n-type compound semiconductor and a second semiconductor layer made of a p-type compound semiconductor, the first semiconductor layer and the second semiconductor layer being formed on the cladding layer, sandwiching the active region, and being each in contact with a side surface of the core;
a third semiconductor layer made of an n-type compound semiconductor, formed on the cladding layer, being disposed so as to sandwich the first semiconductor layer with the active region, and connected to the first semiconductor layer;
a fourth semiconductor layer made of a p-type compound semiconductor, formed on the cladding layer, being disposed so as to sandwich the second semiconductor layer with the active region, and connected to the second semiconductor layer;
a first electrode connected to the third semiconductor layer;
a second electrode connected to the fourth semiconductor layer; and
a first passive optical waveguide and a second passive optical waveguide including the core in two regions sandwiching the active region and connected to the active region, wherein
the first semiconductor layer and the second semiconductor layer are formed to be thinner than the core,
the first semiconductor layer includes a first region having a trapezoidal shape in which a width decreases from the core side toward the third semiconductor layer side in plan view and a first enlarged region having a trapezoidal shape in which a width increases from the first region side toward the third semiconductor layer side,
the second semiconductor layer includes a second region having a trapezoidal shape in which a width decreases from the core side toward the fourth semiconductor layer side in plan view and a second enlarged region having a trapezoidal shape in which a width increases from the second region side toward the fourth semiconductor layer side, and
each of the first region and the second region has, at end portions in a waveguide direction, a tapered shape in which a width in plan view decreases as a distance from a central portion of the active region increases.

### [Supplementary Note 2]

The optical device according to Supplementary note 1, including:
a first recess and a second recess formed in the cladding layer in a region sandwiching the first semiconductor layer in the waveguide direction; and
a third recess and a fourth recess formed in the cladding layer in a region sandwiching the second semiconductor layer in the waveguide direction, wherein
each of the first recess, the second recess, the third recess, and the fourth recess is formed such that an interval between the core increases as a distance from the active region increases.

### [Supplementary Note 3]

The optical device according to Supplementary note 1 or 2, wherein
the first semiconductor layer includes a first neck region that connects the first region and the first enlarged region to each other and has a uniform width from the core side to the third semiconductor layer side in plan view, and
the second semiconductor layer includes a second neck region that connects the second region and the second enlarged region to each other and has a uniform width from the core side to the fourth semiconductor layer side in plan view.

### [Supplementary Note 4]

The optical device according to any one of Supplementary notes 1 to 3, further including
a resonator formed across the active region in the waveguide direction.

### [Supplementary Note 5]

The optical device according to Supplementary note 4, wherein
the resonator is constituted by a photonic crystal structure formed in the core.

### [Supplementary Note 6]

The optical device according to Supplementary note 4, wherein
the resonator includes a diffraction grating formed on the core.

The present invention is not limited to the embodiment described above, and it is apparent that various modifications and combinations can be implemented by those skilled in the art without departing from the technical spirit of the present invention.
[Reference Literature 1] K. Takeda et al, “Optical links on silicon photonic chips using ultralow-power consumption photonic-crystal lasers”, Optics Express 29, Vol. 29, No. 16, pp. 26082-26092, 2021.

### REFERENCE SIGNS LIST

101 Cladding layer
101a First recess
101b Second recess
101c Third recess
101d Fourth recess
102 Core
103 Active layer
104 First semiconductor layer
104a First region
104b First enlarged region
104c First neck region
105 Second semiconductor layer
105a Second region
105b Second enlarged region
105c Second neck region
106 Third semiconductor layer
107 Fourth semiconductor layer
108 First electrode
109 Second electrode
111 Resonator
131 Active region
132 First passive optical waveguide
133 Second passive optical waveguide

1. An optical device comprising:
a cladding layer;
a core made of a compound semiconductor and formed on the cladding layer;
an active layer embedded in an active region of the core;
a first semiconductor layer made of an n-type compound semiconductor and a second semiconductor layer made of a p-type compound semiconductor, the first semiconductor layer and the second semiconductor layer being formed on the cladding layer, sandwiching the active region, and each being formed in contact with a side surface of the core;
a third semiconductor layer made of an n-type compound semiconductor, formed on the cladding layer, being disposed so as to sandwich the first semiconductor layer with the active region, and connected to the first semiconductor layer;
a fourth semiconductor layer made of a p-type compound semiconductor, formed on the cladding layer, being disposed so as to sandwich the second semiconductor layer with the active region, and connected to the second semiconductor layer;
a first electrode connected to the third semiconductor layer;
a second electrode connected to the fourth semiconductor layer; and
a first passive optical waveguide and a second passive optical waveguide including the core in two regions sandwiching the active region and connected to the active region, wherein
the first semiconductor layer includes a first region having a trapezoidal shape in which a width decreases from the core side toward the third semiconductor layer side in plan view and a first enlarged region having a trapezoidal shape in which a width increases from the first region side toward the third semiconductor layer side, and
the second semiconductor layer includes a second region having a trapezoidal shape in which a width decreases from the core side toward the fourth semiconductor layer side in plan view and a second enlarged region having a trapezoidal shape in which a width increases from the second region side toward the fourth semiconductor layer side.

2. The optical device according to claim 1, wherein the cladding layer includes:
a first recess and a second recess formed in a region sandwiching the first semiconductor layer in the waveguide direction; and
a third recess and a fourth recess formed in a region sandwiching the second semiconductor layer in the waveguide direction, wherein
each of the first recess, the second recess, the third recess, and the fourth recess is formed such that an interval between the recess and the core increases as a distance from the active region increases.

3. The optical device according to claim 2, wherein
the first semiconductor layer includes a first neck region that connects the first region and the first enlarged region to each other, and
the second semiconductor layer includes a second neck region that connects the second region and the second enlarged region to each other.

4. The optical device according to claim 1, further comprising:
a resonator formed across the active region in the waveguide direction.

5. The optical device according to claim 4, wherein
the resonator is constituted by a photonic crystal structure formed in the core.

6. The optical device according to claim 4, wherein
the resonator includes a diffraction grating formed on the core.

7. The optical device according to claim 1, wherein the first semiconductor layer and the second semiconductor layer are formed to be thinner than the core.

8. The optical device according to claim 1, wherein each of the first region and the second region includes an end portion in a waveguide direction which is formed in a tapered shape in which a width in a plan view becomes narrower as a distance from a central portion of the active region increases.

9. The optical device according to claim 3, wherein
the first neck region has a uniform width from the core side to the third semiconductor layer side in plan view, and
the second neck region has a uniform width from the core side to the fourth semiconductor layer side in plan view.

10. The optical device according to claim 2, further comprising a resonator formed across the active region in the waveguide direction.

11. The optical device according to claim 3, further comprising a resonator formed across the active region in the waveguide direction.
